(19) United States
(12) Patent Application Publication
(10) Pub. No.: US 2025/0142963 A1
(43) Pub. Date: May 1, 2025

(54) ARRAY SUBSTRATES AND DISPLAY PANELS

(71) Applicant: WUHAN CHINA STAR OPTOELECTRONICS TECHNOLOGY CO., LTD., Wuhan (CN)

(72) Inventors: Zhuang LI, Wuhan (CN); Chunpeng ZHANG, Wuhan (CN); Fei AI, Wuhan (CN); Jianfeng YUAN, Wuhan (CN); Zhifu LI, Wuhan (CN)

(73) Assignee: WUHAN CHINA STAR OPTOELECTRONICS TECHNOLOGY CO., LTD., Wuhan (CN)

(21) Appl. No.: 18/524,299

(22) Filed: Nov. 30, 2023

Related U.S. Application Data
(63) Continuation of application No. PCT/CN2023/130224, filed on Nov. 7, 2023.

(30) Foreign Application Priority Data
Oct. 31, 2023 (CN) 202311449529.7

(51) Int. Cl. H01L 27/12

(52) U.S. Cl. CPC H10D 86/60; H10D 86/421; H10D 86/443

(57) ABSTRACT

An array substrate and a display panel are provided, which include a base and a plurality of semiconductor devices disposed on the base. An active defining portion is provided on the base, a junction of a connecting surface and a first top surface of the active defining portion is a first edge. The semiconductor device includes an active layer and a gate, one or more single crystal starting points of the active layer correspond to the first edge. An area where two rows of single crystal particles parallel to the first edge on both sides of the one or more single crystal starting points is a single crystal area, the channel portion of the active layer is disposed in the single crystal area, and the gate is provided with in a direction perpendicular to the base and covers only one row of the two rows of single crystal particles.

### CROSS REFERENCE TO RELATED APPLICATIONS

This application is a continuation of International Application No. PCT/CN2023/130224, filed on Nov. 7, 2023, which claims priority to Chinese Patent Application No. 202311449529.7, filed in the Chinese Patent Office on Oct. 31, 2023, and entitled “Array Substrates and Display Panels”, the contents of which are incorporated herein by reference in their entirety

### TECHNICAL FIELD

The present disclosure relates to the field of display technologies, and in particular to array substrates and display panels.

### BACKGROUND

Integrating driving circuits, for example, a sub-pixel, a gate driving circuit, a de-multiplexing circuit, a source driving chip, and a timing controller, on a glass substrate (system on glass, SOG) can greatly improve the integration level of a display panel, reduce the dependence on driving chips, and reduce costs. To realize SOG, it is necessary to increase the integration level, maximum operating frequency and current density of a transistor. In order to improve the integration level, maximum operating frequency and current density of a thin film transistor, it is required that the transistor has a shorter channel length, higher mobility and smaller volume.

### SUMMARY

### Technical Problem

Embodiments of the present disclosure provide an array substrate and a display panel, which are conducive to realizing a design of a short channel, high mobility, and small volume for a semiconductor device on the array substrate.

### Technical Solution

An embodiment of the present disclosure provides an array substrate including a base and a plurality of semiconductor devices disposed on the base; wherein an active defining portion is provided on the base, and the active defining portion includes a first bottom surface in contact with a top surface of the base, a first top surface parallel to the first bottom surface and a connecting surface connected between the first top surface and the first bottom surface and is arranged obliquely, wherein a junction of the connecting surface and the first top surface is a first edge, and a junction of the connecting surface and the first bottom surface is a second edge. The semiconductor device includes an active layer and a gate layer. The active layer is disposed on the base and the active defining portion, and the active layer includes a first doped portion, a second doped portion and a channel portion disposed between the first doped portion and the second doped portion. The gate layer includes a gate disposed corresponding to the channel portion, and a gate insulating layer is disposed between the gate layer and the active layer. The active layer includes one or more single crystal starting points, crystal particles of the active layer grow horizontally and diffusely on the base and the active defining portion in a direction perpendicular to the one or more single crystal starting points, and the one or more single crystal starting points correspond to the first edge. An area where two rows of single crystal particles parallel to the first edge on both sides of the one or more single crystal starting points is a single crystal area, the channel portion is disposed in the single crystal area, and the gate is provided with in a direction perpendicular to the base and covers only one row of the two rows of single crystal particles.

An embodiment of the present disclosure provides a display panel, in which the display panel includes any of the above array substrates.

### BRIEF DESCRIPTION OF THE DRAWINGS

FIG. 1 is a schematic structural diagram of a structure of an array substrate in the existing art;

FIG. 2A is a schematic structural diagram of a first structure of an array substrate provided by an embodiment of the present disclosure;

FIG. 2B is a schematic diagram of a first section cut along A-A′ shown in FIG. 2A;

FIG. 2C is a schematic diagram of a first section cut along B-B′ shown in FIG. 2A;

FIG. 2D is a schematic diagram of a second section cut along A-A′ shown in FIG. 2A;

FIG. 2E is a schematic diagram of a second section cut along B-B′ shown in FIG. 2A;

FIG. 2F is a schematic diagram of a third section cut along B-B′ shown in FIG. 2A;

FIG. 2G is a schematic structural diagram of a second structure of an array substrate provided by an embodiment of the present disclosure;

FIG. 2H is a schematic diagram of a first section cut along A-A′ shown in FIG. 2G;

FIG. 2I is a schematic diagram of a first section cut along B-B′ shown in FIG. 2G;

FIG. 2J is a schematic diagram of a second section cut along A-A′ shown in FIG. 2G;

FIG. 2K is a schematic diagram of a second section cut along B-B′ shown in FIG. 2G;

FIG. 2L is a schematic diagram of a third section cut along B-B′ shown in FIG. 2G;

FIG. 3 is a schematic diagram of the relationship between particle sizes of single crystal particles and a length of a connecting surface provided by an embodiment of the present disclosure;

FIG. 4A to FIG. 4F are flowcharts for preparing an array substrate provided by an embodiment of the present disclosure;

FIG. 5A is a top view of a structure of an active layer measured by a scanning electron microscope provided by an embodiment of the present disclosure;

FIG. 5B to FIG. 5C are cross-sectional views of semiconductor devices measured by a scanning electron microscope provided by some embodiments of the present disclosure;

FIG. 6 is a schematic diagram of the characteristic curve of a semiconductor device provided by an embodiment of the present disclosure;

FIG. 7 is a cross-sectional view of a semiconductor device including an insulating pad layer measured by a scanning electron microscope provided by an embodiment of the present disclosure; and

FIG. 8 is a schematic structural diagram of a structure of a display panel provided by an embodiment of the present disclosure.

### DETAILED DESCRIPTION OF THE PREFERRED EMBODIMENTS

In order to make the purpose, technical solution and effect of the present disclosure clearer and more specific, the present disclosure will be described in detail below with reference to the accompanying drawings and the embodiments. It should be understood that the specific embodiments described herein are only used to explain the present disclosure and are not intended to limit the present disclosure.

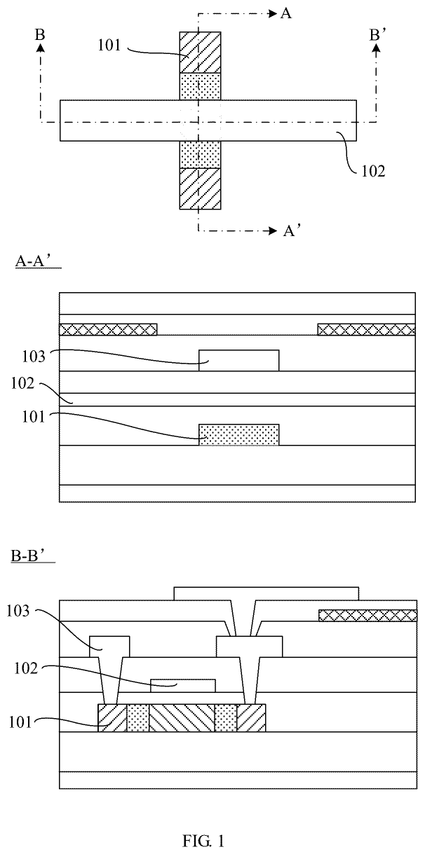

Specifically, FIG. 1 is a schematic structural diagram of a structure of an array substrate in the existing art. At present, an active layer 101 of a semiconductor device as a whole is disposed on a horizontal plane, a gate 102 is disposed on the active layer 101, and a source and drain layer 103 includes a source and a drain that are electrically connected to the active layer 101. Due to the limitation of exposure and etching processes, the channel length of the semiconductor device is generally more than 2 microns, which occupies a large plane area, and there are many crystal boundaries existed within the channel, resulting in a low mobility of the semiconductor device and a large volume of the device.

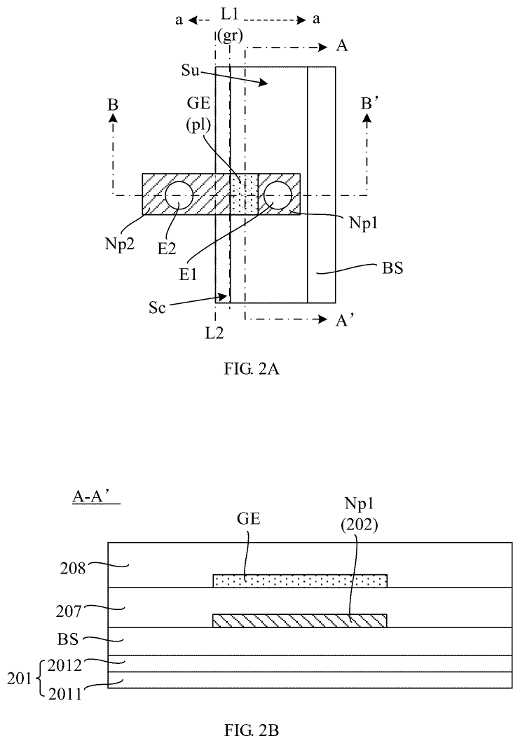

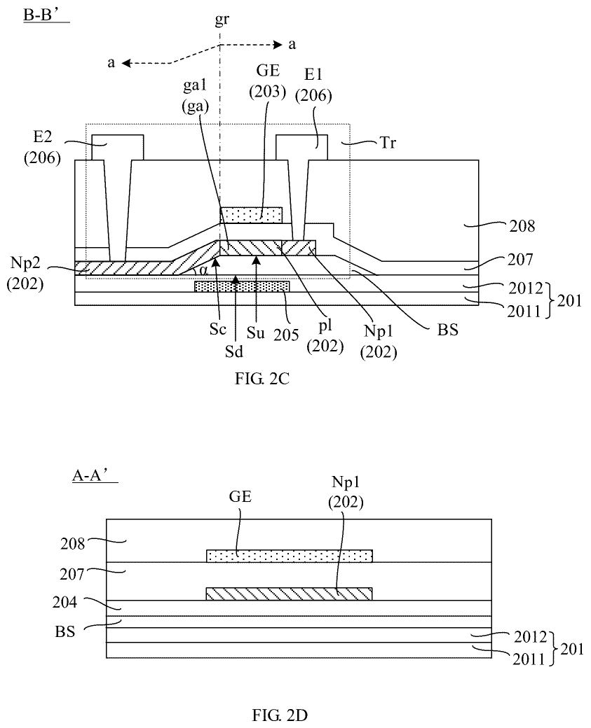

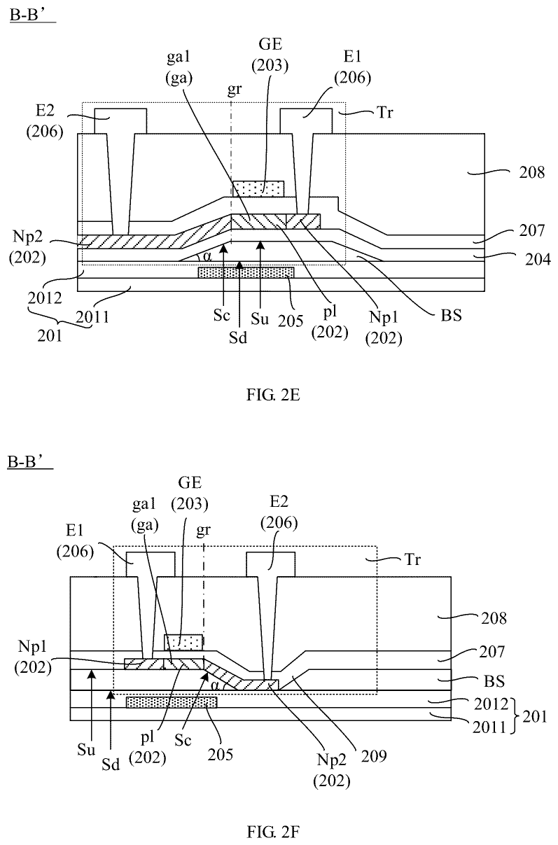

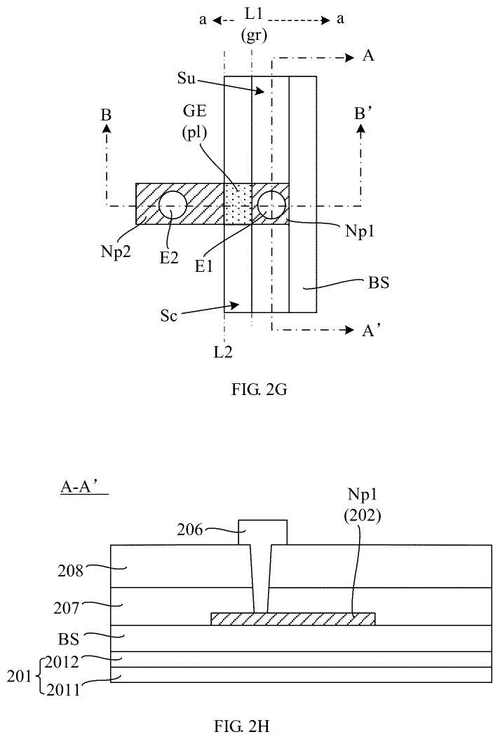

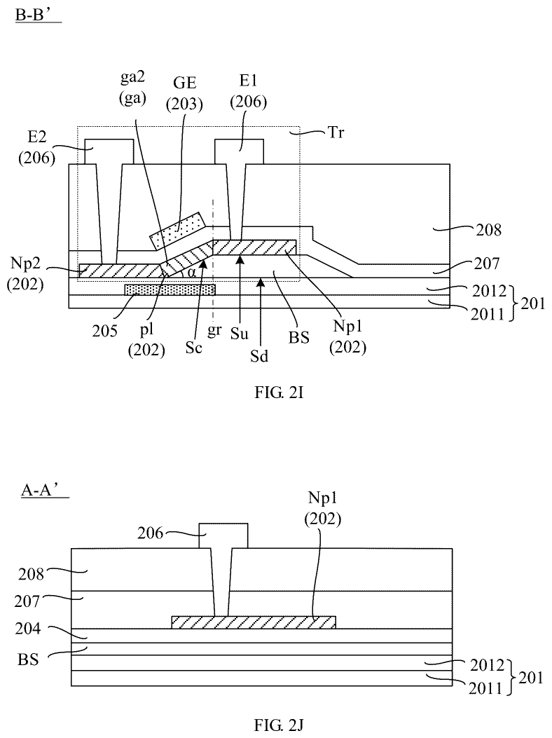

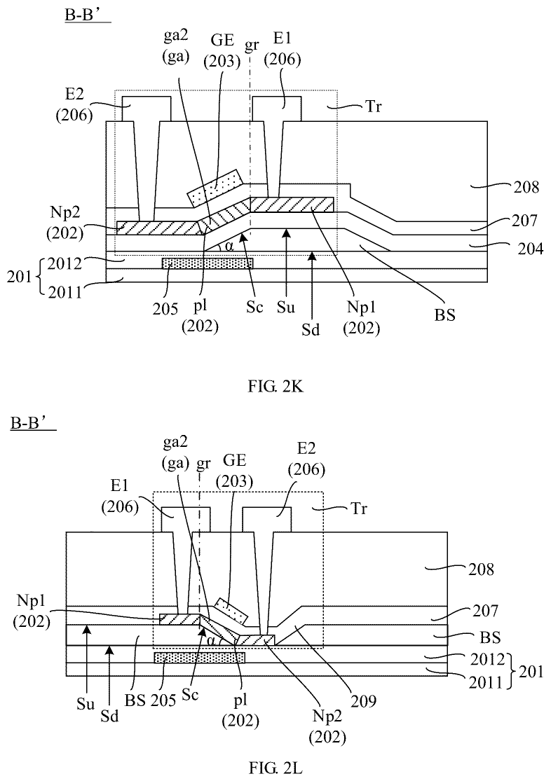

Embodiments of the present disclosure provide an array substrate and a display panel, which are conducive to realizing a design of a short channel, high mobility, and small volume for the semiconductor device included in the array substrate. FIG. 2A is a schematic structural diagram of a first structure of an array substrate provided by an embodiment of the present disclosure. FIG. 2B is a schematic diagram of a first section cut along A-A′ shown in FIG. 2A. FIG. 2C is a schematic diagram of a first section cut along B-B′ shown in FIG. 2A. An embodiment of the present disclosure provides an array substrate, including a base 201 and a plurality of semiconductor devices Tr disposed on the base 201. Optionally, the base 201 includes a basement 2011. The basement 2011 includes two types of basement, a flexible basement and a rigid basement. Thus, the basement 2011 may be a flexible basement, a rigid basement, or a combination of a flexible basement and a rigid basement. Optionally, the basement 2011 includes one or a combination of glass, polyimide, or the like.

An active defining portion BS is provided on the base 201, and the active defining portion BS includes a first bottom surface Sd in contact with a top surface of the base 201, a first top surface Su parallel to the first bottom surface Sd, and a connecting surface Sc connected between the first top surface Su and the first bottom surface Sd and arranged obliquely. A junction of the connecting surface Sc and the first top surface Su is a first edge L1, a junction of the connecting surface Sc and the first bottom surface Sd is a second edge L2.

The active defining portion BS refers to a three-dimensional structure with a height difference and an inclined surface at the connecting position, and the active defining portion BS may be in the shape of a round platform, a prism frustum, etc., for example.

Optionally, a material for preparing the active defining portion BS includes silicon oxide, silicon nitride, and the like.

Optionally, the base 201 further includes a buffer layer 2012, and the buffer layer is disposed on the basement 2011 to provide a better planarization foundation for the active defining portion BS and to prevent or inhibit impurities and moisture from penetrating from the base 201 to the direction of the active layer 202.

Optionally, the buffer layer 2012 includes one or more inorganic insulating layers.

Optionally, the active defining portion BS can be disposed in the same layer as the buffer layer 2012 in the base 201 (that is, the entire buffer layer 2012 is prepared, and then the buffer layer 2012 is etched to form the active defining portion BS).

Continuing to refer to FIG. 2A to FIG. 2C, any one of the plurality of semiconductor devices Tr includes an active layer 202 and a gate layer 203. The active layer 202 is disposed on the base 201 and the active defining portion BS. The active layer 202 includes a first doped portion Np1, a second doped portion Np2, and a channel portion p1 disposed between the first doped portion Np1 and the second doped portion Np2.

The gate layer 203 includes a gate GE disposed corresponding to the channel portion.

Optionally, the gate layer 203 is disposed on the active layer 202, as shown in FIG. 2A to FIG. 2C.

Optionally, the gate layer 203 is disposed below the active layer 202, so that any one of the plurality of semiconductor devices has a bottom gate structure.

The active layer 202 includes one or more single crystal starting points gr, and crystal particles of the active layer 202 grow horizontally and diffusely on the base 201 and the active defining portion BS in a direction perpendicular to one or more single crystal starting points gr (as shown by the dotted arrows, ‘a’, in FIG. 2A and FIG. 2C), the one or more single crystal starting points gr correspond to the first edge L1, that is, the one or more single crystal starting points gr are in a form of a line or an area corresponding to the first edge L1. An area where two rows of single crystal particles parallel to the first edge L1 on both sides of the one or more single crystal starting points gr is a single crystal area ga, the channel portion p1 is disposed in the single crystal area ga, and the gate GE is provided with and covers only one row of the two rows of single crystal particles in a direction perpendicular to the base.

It should be noted that the gate GE is provided with and covers only one row of the two rows of single crystal particles in the direction perpendicular to the base, including: a positive projection of the gate GE on the base 201 coincides with a positive projection of a corresponding row of the two rows of single crystal particles on the base 201; or, the positive projection of the gate GE on the base 201 is located within the positive projection of the corresponding row of the two rows of single crystal particles on the base 201.

By enabling the gate GE to correspond to the channel portion p1, and by arranging the gate GE to correspond to one row of the two rows of single crystal particles, the channel portion p1 is disposed corresponding to one row of the two rows of single crystal particles. And one or more starting points of single crystal particles of the row of the two rows of single crystal particles corresponding to the channel portion p1 are located at the first edge L1, so that the gate GE does not correspond to the crystal boundary. Thus, a channel length of the semiconductor device is determined by particle sizes of single crystal particles in the row of the two rows of single crystal particles corresponding to the gate GE, thereby reducing the channel length of the semiconductor device, which is beneficial to improving the mobility and on-state current of the semiconductor device and other electrical properties, and is beneficial to realizing the design of a short channel and high-mobility for the semiconductor device.

In addition, compared with the design of the existing art as shown in FIG. 1, in which the whole of the active layer is disposed on a same horizontal plane, the present disclosure can reduce the projection area of the active layer 202 on the base 201 by disposing at least a part of the active layer 202 on the active defining portion BS, so that the active layer 202 can reduce the volume of the semiconductor device while satisfying the design performance requirements.

Optionally, the active defining portion BS is in the shape of a round platform, and the connecting surface Sc is provided between the first top surface Su and the first bottom surface Sd. The active layer 202 may cover the entire connecting surface Sc, or may partially cover the connecting surface Sc.

Optionally, when the gate GE covers one row of the two rows of single crystal particles disposed on the connecting surface Sc in the direction perpendicular to the base 201, the active layer 202 covers the entire connecting surface Sc, so that the channel width of the semiconductor device is equal to the circumference of the connecting surface Sc, thereby increasing the channel width of the semiconductor device and improving the on-state current of the semiconductor device.

Optionally, the active layer 202 partially covers the connecting surface Sc, so as to reduce the area occupied by the active layer 202 while meeting the performance requirements.

Optionally, in the case where the active defining portion BS is in a prism frustum shape, a plurality of connecting surfaces Sc are correspondingly disposed between the first top surface Su and the first bottom surface Sd, and the active layer 202 may be disposed corresponding to a partial area where at least one of the connecting surfaces Sc is located.

Optionally, when the channel portion p1 covers a part of the active defining portion BS, in a first direction (the same direction as the cutting direction along A-A′ in FIG. 2A), a size of the active defining portion BS is greater than or equal to a size of the active layer 202, so that the active defining portion BS has an area large enough for the active layer 202 to be completely prepared on the active defining portion BS. A second direction refers to a direction pointed from the first edge L1 to the second edge L2 (the same direction as the cutting direction along B-B′ in FIG. 2A and FIG. 2G), and the second direction can be perpendicular to the first direction.

Continuing to refer to FIG. 2A to FIG. 2C, in order to enable the one or more single crystal starting points gr to correspond to the first edge L1 (that is, the one or more starting points of single crystal particles of one row of the two rows of single crystal particles corresponding to the channel portion p1 can be located at a junction of the first surface Su and the connecting surface Sc), and reduce the length of the connecting surface Sc, an included angle α can be formed between the first bottom surface Sd and the connecting surface Sc, and the included angle α is less than or equal to 45°.

Optionally, the included angle α is equal to 44°, 43°, 42°, 41°, 40°, 36°, 35°, 34°, 32°, 31°, 30°, 26°, 25°, 24°, 20°, 16°, 15°, 14°, 10°, 8°, 5° or 1°.

Optionally, in order to prevent the included angle α from being too small, in which case the first edge L1 cannot be used as the one or more single crystal starting points of the row of the two rows of single crystal particles corresponding to the channel portion p1, and the first edge L1 cannot play a role of positioning. The included angle α may be greater than or equal to 15°.

Optionally, in order to avoid the disconnection and film rupture of the active layer 202 caused by the occurrence of cracks in the active layer 202 at the junction of the first top surface Su and the connecting surface Sc and the junction of the first bottom surface and the connecting surface Sc during the preparation process, the included angle α may be less than or equal to 30° so as to ensure that the active layer 202 can have a good crystallization effect when forming crystal particles by adopting the existing Excimer Laser Annealing (ELA) process.

Preferably, in order to balance the crystallization and film formation effect of the active layer 202 as well as the positioning effect of the first edge L1, the included angle α is greater than or equal to 15° and less than or equal to 30°. Optionally, the included angle α is greater than or equal to 15° and less than or equal to 30°.

FIG. 2D is a schematic diagram of a second section cut along A-A′ shown in FIG. 2A, and FIG. 2E is a schematic diagram of a second section cut along B-B′ shown in FIG. 2A. The array substrate includes an insulating pad layer 204 disposed on a side surface of the active layer 202 close to the base 201, and the insulating pad layer 204 is disposed on the base 201 and the active defining portion BS. The material for preparing the insulating pad layer 204 includes silicon oxide, so that the insulating pad layer 204 and the active layer 202 can be continuously formed (that is, the insulating pad layer 204 is prepared below the active layer 202) when the active layer 202 is prepared, reducing back channel defects of the active layer 202 (that is, crystal defect states exist on a surface of a side of the active layer 202 close to the base 201), and improving the electrical performance of the transistor.

In practice, after the base 201 and the active defining portion BS are prepared, the active layer 202 will be prepared after a long time interval. Therefore, there will be contamination on the surfaces of the base 201 and active defining portion BS, causing the prepared active layer 202 to be affected by the contaminants, so that crystal defect states are presented on the surfaces of the active layer 202 in contact with the base 201 and the first top surface Su of the active defining portion BS, which affects the performance of the active layer 202.

Optionally, the insulating pad layer 204 may be disposed only corresponding to the channel portion p1. Optionally, after the active layer 202 is etched, the hydrofluoric acid can be used to etch the insulating pad layer 204, so that the insulating pad layer 204 is only disposed corresponding to the channel portion p1.

Optionally, since the insulating pad layer 204 located below the active layer 202 cannot be completely patterned when the active layer 202 is etched, the insulating pad layer 204 may not only be disposed corresponding to the channel portion p1, but also be disposed corresponding to the first doped portion Np1, the second doped portion Np2, and the like.

Optionally, continuing to refer to FIG. 2A to FIG. 2E, at least one of the active defining portion BS and the insulating pad layer 204 can also be reused as a barrier layer, so as to prevent or inhibit impurities and moisture from penetrating from the base 201 to a direction of the active layer 202, reducing the volume of the semiconductor device.

Optionally, the active defining portion BS includes a protruding portion, as shown in FIG. 2C and FIG. 2E.

FIG. 2F is a schematic diagram of a third section cut along B-B′ shown in FIG. 2A. The active defining portion BS includes a groove, an inclined surface of the groove forms the connecting surface Sc of the active defining portion BS, a portion of the groove in contact with the base 201 and connected with the inclined surface of the groove forms the first bottom surface Sd of the active defining portion BS, and a portion of the groove parallel with the first bottom surface Sd and connected with the inclined surface of the groove forms the first top surface Su of the active defining portion BS.

Continuing to refer to FIG. 2A to FIG. 2F, any one of the plurality of semiconductor devices further includes a light shielding layer 205. The light shielding layer 205 is disposed within the base 201, and the light shielding layer 205 includes a light shielding portion disposed corresponding to the channel portion p1, so as to reduce the impact of light on the semiconductor device.

Optionally, the light shielding layer 205 is disposed between the buffer layer 2012 and the basement 2011.

Optionally, since the one or more single crystal starting points gr correspond to the first edge L1, and crystal particles included in the active layer 202 grow horizontally and diffusely in a direction perpendicular to the one or more single crystal starting points gr, crystal particles can grow from the one or more single crystal starting points gr to the first top surface Su and the connecting surface Sc, so that one row of the two rows of single crystal particles is located on the first top surface Su, and another row of the two rows of single crystal particles is located on the connecting surface Sc. When crystal particles grow toward the first top surface Su and the connecting surface Sc, crystal boundaries between the crystal particles are correspondingly located at the first edge L1.

Accordingly, the row of the two rows of single crystal particles corresponding to the channel portion p1 may be located on the first top surface Su, as shown in FIG. 2A and FIG. 2C.

Alternatively, the row of the two rows of single crystal particles corresponding to the channel portion p1 may be located on the connecting surface Sc. Specifically, FIG. 2G is a schematic structural diagram of a second structure of an array substrate provided by an embodiment of the present disclosure; FIG. 2H is a schematic diagram of a first section cut along A-A′ shown in FIG. 2G; and FIG. 2I is a schematic diagram of a first section cut along B-B′ shown in FIG. 2G.

Optionally, the single crystal area ga includes a first single crystal area gal (as shown in FIG. 2C, FIG. 2E, and FIG. 2F). The first single crystal area gal includes a row of the two rows of single crystal particles located on the first top surface Su. The single crystal area ga includes a second single crystal area ga2 (as shown in FIG. 21, FIG. 2K, and FIG. 2L). The second single crystal area ga2 includes a row of the two rows of single crystal particles covering the connecting surface Sc. The gate GE may be disposed corresponding to the first single crystal area ga1, as shown in FIG. 2A to FIG. 2F; and/or, the gate GE may be disposed corresponding to the second single crystal area ga2, as shown in FIG. 2G to FIG. 2I.

Specifically, continuing to refer to FIG. 2A to FIG. 2F, the gate GE covers a row of the two rows of single crystal particles located on the first top surface Su in the direction perpendicular to the base 201. The first doped portion Np1 is located on the first top surface Su, and the second doped portion Np2 is located on the base 201 and the connecting surface Sc.

A positive projection of the gate GE on the base 201 has a first boundary, and a positive projection of a row of the two rows of single crystal particles located on the first top surface Su on the base 201 has a second boundary. It should be noted that the gate GE covers a row of the two rows of single crystal particles located on the first top surface Su in the direction perpendicular to the base 201, including: the first boundary is located within the second boundary, or, the first boundary coincides with the second boundary.

Optionally, the gate GE is disposed corresponding to the first single crystal area ga1, so that the gate GE can be disposed parallel to the base 201. Therefore, the gate GE can remain a uniform film thickness while improving the mobility, on-state current and other electrical properties of the semiconductor device. It is conducive to reducing the process difficulty of preparing the semiconductor device.

Optionally, continuing to refer to FIG. 2G to FIG. 2I, the gate GE covers a row of the two rows of single crystal particles located on the connecting surface Sc in the direction particular to the base 201. The first doped portion Np1 is located on the first top surface Su, and the second doped portion Np2 is located on the base 201.

The positive projection of the gate GE on the base 201 has a first boundary, and the positive projection of a row of the two rows of single crystal particles located on the connecting surface Sc on the base 201 has a third boundary. It should be noted that the gate GE covers a row of the two rows of single crystal particles located on the connecting surface Sc in a direction particular to the base 201, including: the first boundary is located within the third boundary, and the first boundary coincides with the third boundary.

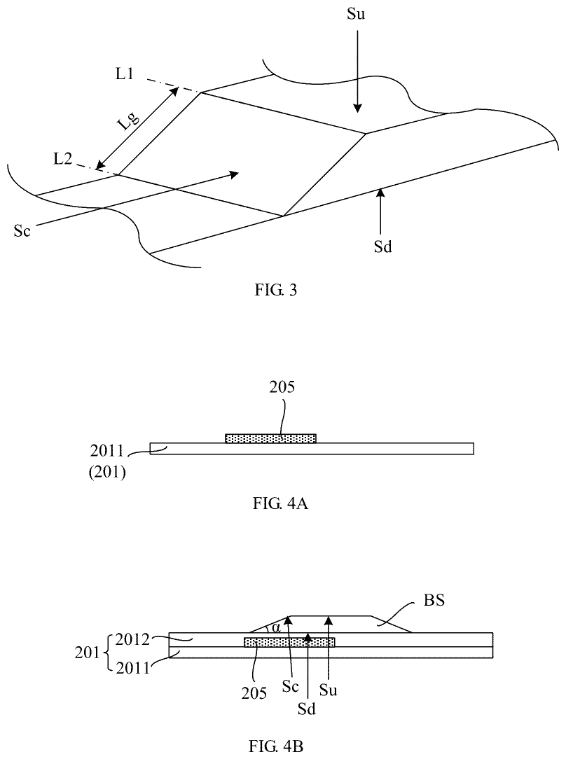

FIG. 3 is a schematic diagram of the relationship between particle sizes of single crystal particles and a length of a connecting surface provided by an embodiment of the present disclosure. When the gate GE is disposed corresponding to the second single crystal area ga2, on the connecting surface Sc, particle sizes of single crystal particles in the row of the two rows of single crystal particles in the second single crystal area ga2 are greater than a distance between the first edge L1 and the second edge L2 (that is, shown by Lg in FIG. 3). Therefore, in a direction pointing from the first edge L1 to the second edge L2, a length of the row of the two rows of single crystal particles included in the second single crystal area ga2 is greater than or equal to the length of the connecting surface Sc. Therefore, a portion of the channel portion p1 corresponded to the gate GE is made of single crystal particles, thereby improving the mobility of the semiconductor device.

Optionally, the gate GE is disposed corresponding to the second single crystal area ga2, an end point of the row of the two rows of single crystal particles included in the second single crystal area ga2 is located at a side of the second edge L2 away from the first edge L1, so that particle sizes of single crystal particles of the row of the two rows of single crystal particles included in the second single crystal area ga2 are greater than the length of the connecting surface Sc, thereby ensuring that a portion of the channel portion p1 corresponding to the gate GE is made of single crystal particles, and further ensuring that the mobility, on-state current and other electrical properties of the semiconductor device are improved.

Optionally, in the direction pointing from the first edge L1 to the second edge L2, the length of the connecting surface Sc may be from 0.1 micron to 0.7 microns. In the direction pointing from the first edge L1 to the second edge L2, particle sizes of single crystal particles of the row of the two rows of single crystal particles included in the second single crystal area ga2 may be in the range from 0.1 micron to 0.7 microns. Optionally, in the direction pointing from the first edge L1 to the second edge L2, the length of the connecting surface Sc may be equal to 0.1 micron, 0.2 microns, 0.3 microns, 0.4 microns, 0.5 microns, 0.6 microns, 0.7 microns. In the direction pointing from the first edge L1 to the second edge L2, particle sizes of single crystal particles of the row of the two rows of single crystal particles included in the second single crystal area ga2 may be equal to 0.1 micron, 0.2 microns, 0.3 microns, and 0.4 microns, 0.5 microns, 0.6 microns, 0.7 microns, 0.8 microns, 0.9 microns, 1 micron, 1.2 microns, 1.5 microns, and the like.

Optionally, in the direction pointing from the first edge L1 to the second edge L2, the length of the connecting surface Sc is equal to 0.4 microns. In the direction pointing from the first edge L1 to the second edge L2, the length of the second single crystal area ga2 (that is, particle sizes of single crystal particles in the row of the two rows of single crystal particles) is greater than or equal to 0.4 microns, so as to balance the performance requirements and volume requirements of the semiconductor.

FIG. 2J is a schematic diagram of a second section cut along A-A′ shown in FIG. 2G, and FIG. 2K is a schematic diagram of a second section cut along B-B′ shown in FIG. 2G. When the gate GE is disposed corresponding to the second single crystal area ga2, the array substrate may still include an insulating pad layer 204.

FIG. 2L is a schematic diagram of a third section cut along B-B′ shown in FIG. 2G. Optionally, when the gate GE is disposed corresponding to the second single crystal area ga2, the active defining portion BS may still include a groove correspondingly.

Optionally, when crystal particles are formed by using the existing excimer laser annealing process, the laser energy and scanning speed of the excimer laser annealing process can be controlled, so that the row of the two rows of single crystal particles included in the second single crystal area ga2 covers the connecting surface Sc.

Optionally, continuing to refer to FIG. 2A to FIG. 2L, whether the gate GE is disposed corresponding to the first single crystal area gal, or the gate GE is disposed corresponding to the second single crystal area ga2, the length of the gate GE in the direction pointing from the first edge L1 to the second edge L2 is less than or equal to the length of a corresponding row of the two rows of single crystal particles, thereby reducing the probability that the gate GE corresponds to crystal boundaries of the channel portion p1, and reducing the impact of process factors on the performance of the semiconductor device. For example, displacement deviation during the process causes the preparation position of the gate GE deviate from the expected position, causing the gate GE to correspond to crystal boundaries; and changes in material properties during the preparation process cause the gate GE to move beyond the original expected position, causing the gate GE to correspond to the crystal boundaries, and the like. And thus, the semiconductor device can meet the design requirements of a short channel, high mobility and small volume.

Optionally, when the gate GE is disposed corresponding to the second single crystal area ga2, a length of a corresponding portion of the light shielding portion beyond the first edge L1 is less than or equal to a length of a corresponding portion of the light shielding portion beyond the second edge L2, so that the light shielding portion can still effectively shield crystal particles included in the second single crystal area ga2 when crystal particles located on the connecting surface Sc exceed far beyond the second edge L2 during the manufacturing process.

Continuing to refer to FIG. 2A to FIG. 2L, the array substrate further includes a source and drain layer 206. The source and drain layer 206 is disposed on the active layer 202, and the source and drain layer 206 includes a first electrode E1 electrically connected to the first doped portion Np1 and a second electrode E2 electrically connected to the second doped portion Np2. The first electrode E1 is one of the source and the drain, and the second electrode E2 is another one of the source and the drain.

Optionally, continuing to refer to FIG. 2A to FIG. 2L, the array substrate further includes a gate insulating layer 207. The gate insulating layer 207 is disposed between the active layer 202 and the gate layer 203 to separate the active layer 202 and the gate layer 203 apart.

Optionally, the gate insulating layer 207 may have a single-layer film structure or a stacked structure of multiple film layers.

Optionally, the array substrate further includes an interlayer dielectric layer 208, and the interlayer dielectric layer 208 is disposed between the source and drain layer 206 and the gate layer 203. The first electrode E1 is electrically connected to the first doped portion Np1 through a via throughout the interlayer dielectric layer 208 and the gate insulating layer 207, and the second electrode E2 is electrically connected to the second doped portion Np2 through a via throughout the interlayer dielectric layer 208 and the gate insulating layer 207.

Optionally, the second doped portion Np2 extends along the second direction, so that the overlapping area between the wires and the semiconductor device is reduced, thereby reducing the parasitic capacitance, when the semiconductor device is electrically connected to the corresponding wires (such as a data wire, a power wire, and other signal wires).

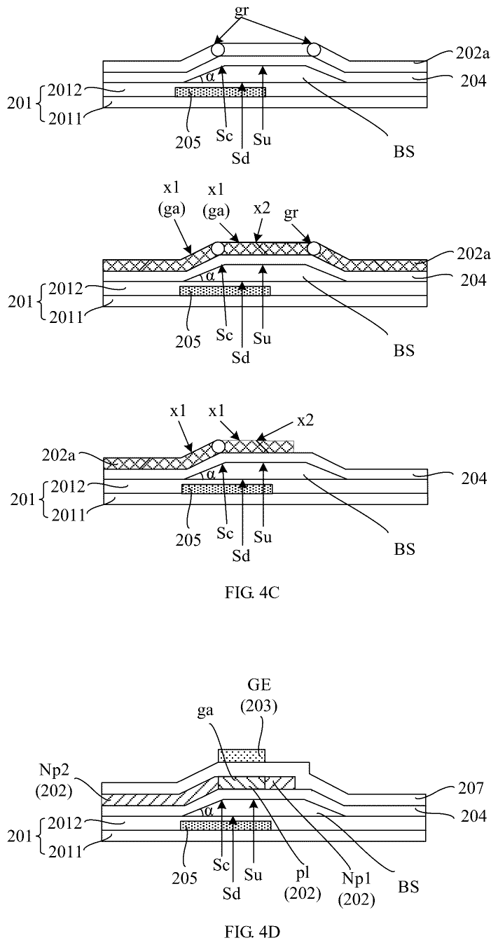

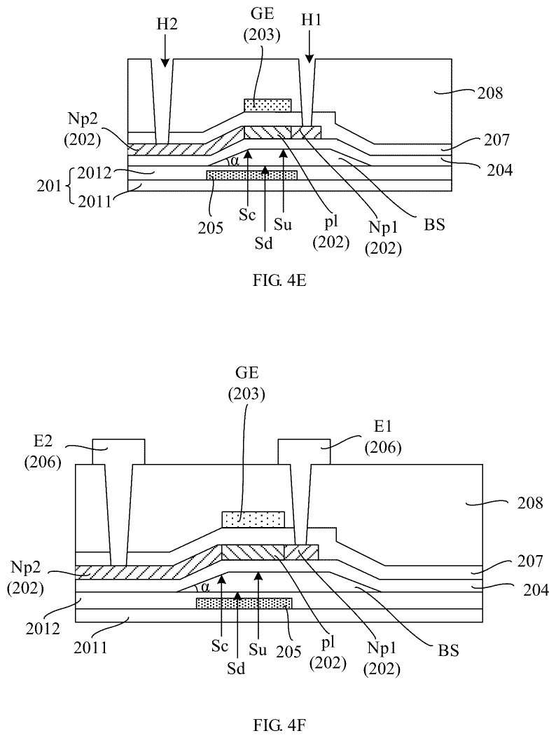

FIG. 4A to FIG. 4F are flowcharts for preparing an array substrate provided by an embodiment of the present disclosure. The present disclosure further provides a method for preparing an array substrate to prepare any of the above array substrates.

The method of manufacturing the array substrate includes the following operations.

Preparing an active defining portion BS on a base 201, as shown in FIG. 4A to FIG. 4B. The active defining portion BS includes a first bottom surface Sd in contact with a top surface of the base 201, a first top surface Su parallel to the first bottom surface Sd, and a connecting surface Sc connected between the first top surface Su and the first bottom surface Sd and arranged obliquely.

Preparing an active layer 202 on the base 201 and the active defining portion BS. The active layer 202 includes one or more single crystal starting points gr, and crystal particles of the active layer 202 grow horizontally and diffusely on the base 201 and the active defining portion BS in a direction perpendicular to the one or more single crystal starting points gr. The one or more single crystal starting points gr correspond to a junction of the first top surface Su and the connecting surface Sc. An area where two rows of single crystal particles parallel to the first edge L1 on both sides of the one or more single crystal starting points gr is a single crystal area ga, the channel portion p1 of the active layer 202 is disposed in the single crystal area ga, as shown in FIG. 4C to FIG. 4D. The one or more single crystal starting points gr correspond to the crystal boundaries, x1 represents a single row of single crystal particles, and x2 represents the crystal boundaries.

Preparing a gate insulating layer 207 and a gate layer 203 on the active layer 202, as shown in FIG. 4D. The gate layer 203 includes a gate GE disposed corresponding to the channel portion p1 of the active layer 202. The gate GE is provided with and covers only one row of the two rows of single crystal particles in a direction perpendicular to the base 201.

Preparing an interlayer dielectric layer 208 on the gate layer 203 and the gate insulating layer 207. The interlayer dielectric layer 208 includes a first via H1 and a second via H2. The first via H1 exposes the first doped portion Np1 of the active layer 202, and the second via H2 exposes the second doped portion Np2 of the active layer 202, as shown in FIG. 4E.

Preparing a source and drain layer 206 on the interlayer dielectric layer 208. The source and drain layer 206 includes a first electrode E1 and a second electrode E2. The first electrode E1 is electrically connected to the first doped portion Np1 through the first via H1, and the second electrode E2 is electrically connected to the second doped portion Np2 through the second via H2, as shown in FIG. 4F.

Optionally, before the operation of preparing an active defining portion BS on the base 201, the method includes: preparing a buffer layer 2012 on a basement 2011, as shown in FIG. 4A to FIG. 4B. Optionally, the base 201 includes the basement 2011 and the buffer layer 2012; and a material for preparing the buffer layer 2012 include silicon oxide or silicon nitride, etc.

Optionally, before the operation of preparing an active defining portion BS on the base 201, the method includes: preparing a light shielding layer 205 on the basement 2011, as shown in FIG. 4A to FIG. 4B. The light shielding layer 205 includes a light shielding portion disposed corresponding to the channel portion p1.

Optionally, a material for preparing the active defining portion BS includes silicon oxide, silicon nitride, or the like.

Optionally, in the operation of preparing an active defining portion BS on the base 201, the method includes: preparing the active defining portion BS and an insulating pad layer 204 on the base 201, as shown in FIG. 4C. The insulating pad layer 204 is disposed on the active defining portion BS and the base 201.

Optionally, a material for preparing the insulating pad layer 204 includes silicon oxide. When the active layer 202 is deposited, the active layer 202 and the insulating pad layer 204 are continuously formed to reduce the back channel defects of the active layer 202 and improve the electrical performance of the semiconductor device.

Optionally, in the operation of preparing the active layer 202 on the base 201 and the active defining portion BS, the method includes: preparing a semiconductor layer 202a on the base 201 and the active defining portion BS, performing a doping process on the semiconductor layer 202a according to the first doped portion Np1 and the second doped portion Np2, and performing a patterning process on the semiconductor layer 202a to obtain the active layer 202, as shown in FIG. 4C to FIG. 4D.

Optionally, the semiconductor layer 202a includes silicon semiconductor material (such as single crystal silicon, amorphous silicon, or the like).

Optionally, the material for preparing the gate insulating layer 207 includes silicon nitride, silicon oxide, or the like. The material for preparing the gate layer 203 includes at least one of the following: molybdenum, titanium, nickel, aluminum, copper, silver, etc. The material for preparing the interlayer dielectric layer 208 include silicon nitride, silicon oxide, or the like. The material for preparing the source and drain layer 206 includes at least one of molybdenum, titanium, nickel, aluminum, copper, silver, or the like.

Optionally, the array substrate further includes a planar layer disposed on the source and drain layer 206.

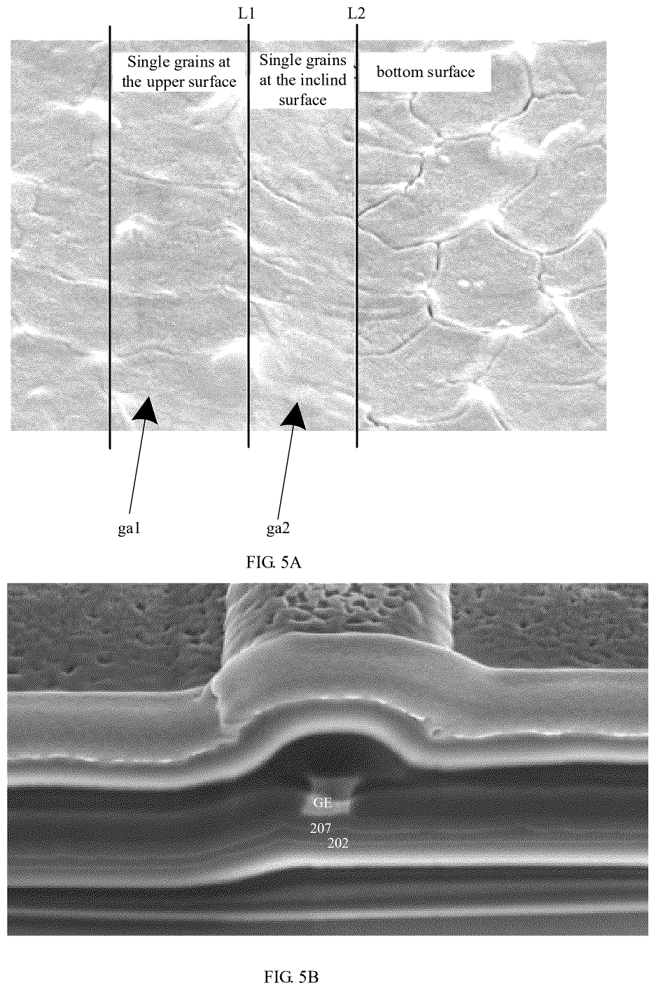

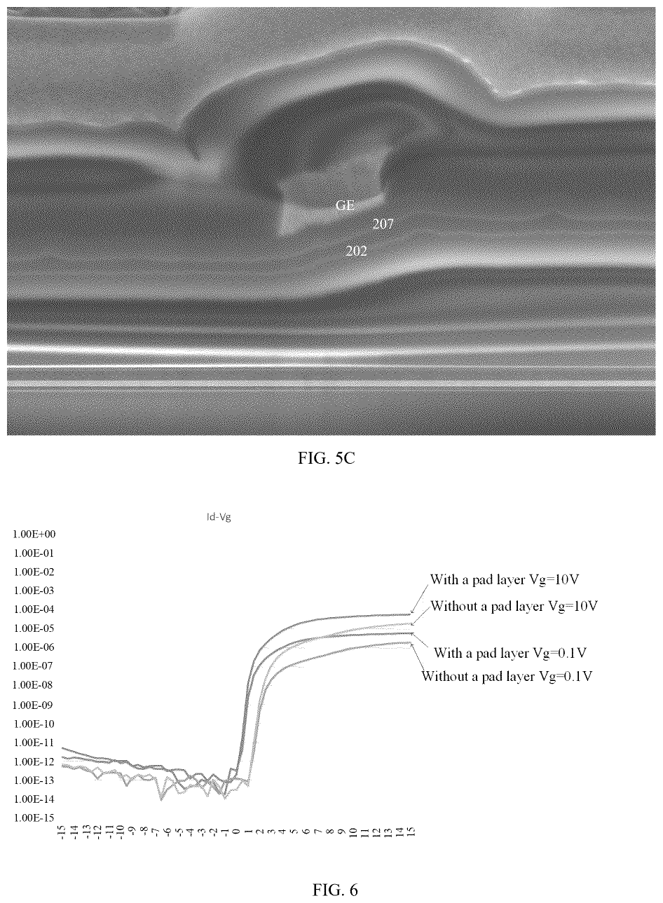

FIG. 5A is a top view of a structure of an active layer measured by a scanning electron microscope provided in an embodiment of the present disclosure. The applicant of the present disclosure has actually verified the array substrate of the present disclosure. In the test of the array substrate, crystal particles of the channel portion p1 in the semiconductor device take the first edge L1 of the active defining portion BS as the starting point, and crystal particles grow along the connecting surface Sc of the active defining portion BS and the first top surface Su of the active defining portion BS (that is, the first edge L1 plays a role in positioning the crystal particles). For crystal particles on the connecting surface Sc of the active defining portion BS, the length of the connecting surface Sc of the active defining portion BS can be controlled so that crystal particles cover the entire connecting surface Sc.

FIG. 5B to FIG. 5C are cross-sectional views of semiconductor devices measured by a scanning electron microscope provided by some embodiments of the present disclosure. In the semiconductor device shown in FIG. 5B, the gate GE is disposed on the first top surface Su of the active defining portion BS. In the semiconductor device shown in FIG. 5C, the gate GE is disposed on the connecting surface Sc of the active defining portion BS. Analysis of the actually obtained semiconductor device through a scanning electron microscope can verify that crystal boundaries are located at the first edge L1 of the active defining portion BS, that is, the starting points of crystal particles are located at the first edge L1. In the direction pointing from the first edge L1 to the second edge L2, the extending distance of the crystal boundaries corresponding to the first edge L1 is smaller than the extending distance of the crystal boundaries corresponding to the second edge L2, and single crystal particles cover on the connecting surface Sc of the active defining portion BS.

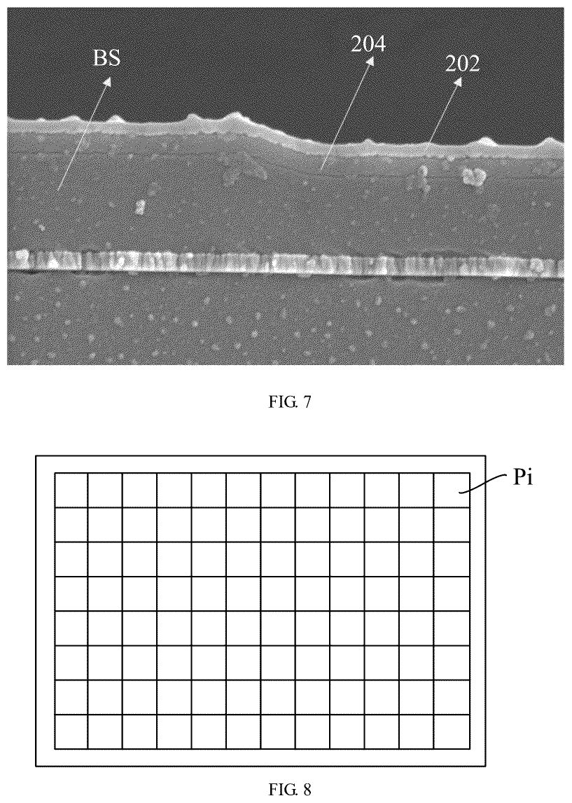

FIG. 6 is a schematic diagram of the characteristic curve of a semiconductor device provided by an embodiment of the present disclosure. FIG. 7 is a cross-sectional view of a semiconductor device including an insulating pad layer measured by a scanning electron microscope provided by an embodiment of the present disclosure. The applicant of the present disclosure has actually verified the design of the semiconductor device of the present disclosure. Comparing the transferring curves of the semiconductor device including the insulating pad layer 204 with those of the semiconductor device not including the insulating pad layer 204, it is found that the semiconductor device not including the insulating pad layer 204 has many back channel defects, including the mobility of the semiconductor device that does not include the insulating pad layer 204 is only about half of the mobility of the semiconductor device that includes the insulating pad layer 204. Moreover, compared with the semiconductor device including the insulating pad layer 204, the uniformity of the semiconductor device not including the insulating pad layer 204 is poorer.

The semiconductor device provided by the present disclosure can be manufactured under the existing technology, which is beneficial to improving the integration level, maximum operating frequency and current density of the device, thereby realizing the integrated design of the driving circuit on the glass substrate.

FIG. 8 is a schematic structural diagram of a structure of a display panel provided by an embodiment of the present disclosure. An embodiment of the present disclosure also provides a display panel, and the display panel includes any of the above array substrates.

Optionally, the display panel includes a passive light-emitting display panel (such as a liquid crystal display panel, a reflective display panel, etc.), a self-light-emitting display panel (such as a display panel including organic light-emitting diodes, sub-millimeter light-emitting diodes, micro-light-emitting diodes and other light-emitting devices).

Optionally, the display panel includes a plurality of sub-pixels Pi and a plurality of pixel driving circuits. Each of the plurality of sub-pixels Pi is electrically connected to a corresponding pixel driving circuit of the plurality of pixel driving circuits, and any one of the plurality of pixel driving circuits includes one or more of the plurality of semiconductor devices.

Optionally, the display panel includes a driving module electrically connected to one or more of the plurality of sub-pixels Pi, and the driving module includes one or more of the plurality of semiconductor devices.

The present disclosure further provides a display device including any of the above array substrates.

Optionally, the display device includes a television, a computer, a mobile phone, a bracelet, or the like.

### Advantageous Effects

Compared with the existing art, embodiments of the present disclosure provide an array substrate and a display panel containing the same. The array substrate includes a base and a plurality of semiconductor devices disposed on the base, in which an active defining portion is provided on the base, and the active defining portion includes a first bottom surface in contact with a top surface of the base, a first top surface parallel to the first bottom surface and a connecting surface connected between the first top surface and the first bottom surface and is disposed obliquely. A junction of the connecting surface and the first top surface is a first edge, a junction of the connecting surface and the first bottom surface is a second edge. The plurality of semiconductor devices includes an active layer and a gate layer. The active layer is disposed on the base and the active defining portion, and includes a first doped portion, a second doped portion and a channel portion disposed between the first doped portion and the second doped portion; the gate layer includes a gate disposed corresponding to the channel portion, and a gate insulating layer is disposed between the gate layer and the active layer. The active layer includes one or more single crystal starting points, and the one or more single crystal starting points correspond to the first edge. Crystal particles of the active layer grow horizontally and diffusely on the base and the active defining portion in a direction perpendicular to the one or more single crystal starting points. An area where two rows of single crystal particles parallel to the first edge on both sides of the one or more single crystal starting points is a single crystal area, the channel portion is disposed in the single crystal area, and the gate is provided with in a direction perpendicular to the base and covers only one row of the two rows of single crystal particles. Therefore, a channel length of the semiconductor device is determined by particle sizes of single crystal particles of a row of the two rows of single crystal particles corresponding to the gate, and the gate no longer corresponds to the crystal boundary, which is conducive to improving the mobility of the semiconductor device and enabling the semiconductor device to achieve a design of a short channel and small volume.

The principles and implementations of the disclosure are explained through specific embodiments, and the description of the above embodiments is only intended to help understand the method and its core idea of the disclosure. At the same time. for those skilled in the art, there will be changes in the specific embodiments and application scope based on the ideas of the present disclosure. In summary. the content of this description should not be understood as a limitation of the present disclosure.

What is claimed is:

1. An array substrate comprising a base and a plurality of semiconductor devices disposed on the base;
wherein an active defining portion is provided on the base, and the active defining portion comprises a first bottom surface in contact with a top surface of the base, a first top surface parallel to the first bottom surface, and a connecting surface connected between the first top surface and the first bottom surface and arranged obliquely, wherein a junction of the connecting surface and the first top surface is a first edge, and a junction of the connecting surface and the first bottom surface is a second edge;
wherein any one of the plurality of semiconductor devices comprises:
an active layer, wherein the active layer is disposed on the base and the active defining portion, and comprises a first doped portion, a second doped part and a channel portion disposed between the first doped portion and the second doped portion; and
a gate layer, wherein the gate layer comprises a gate disposed corresponding to the channel portion, and a gate insulating layer is disposed between the gate layer and the active layer;
wherein the active layer comprises one or more single crystal starting points, the one or more single crystal starting points correspond to the first edge, crystal particles of the active layer grow horizontally and diffusely on the base and the active defining portion in a direction perpendicular to the one or more single crystal starting points; an area where two rows of single crystal particles parallel to the first edge on both sides of the one or more single crystal starting points is a single crystal area, the channel portion is disposed in the single crystal area, and the gate is provided with in a direction perpendicular to the base and covers only one row of the two rows of single crystal particles.

2. The array substrate according to claim 1, wherein an included angle is formed between the first bottom surface and the connecting surface, and the included angle is less than 45°.

3. The array substrate according to claim 2, wherein the included angle is greater than or equal to 15° and less than or equal to 30°.

4. The array substrate according to claim 1, wherein the gate covers one row of the two rows of single crystal particles disposed on the first top surface in the direction perpendicular to the base;
wherein the first doped portion is disposed on the first top surface, and the second doped portion is disposed on the base and the connecting surface.

5. The array substrate according to claim 1, wherein the gate covers one row of the two rows of single crystal particles disposed on the connecting surface in the direction perpendicular to the base;
wherein the first doped portion is disposed on the first top surface, and the second doped portion is disposed on the base.

6. The array substrate according to claim 1, wherein the single crystal area comprises a first single crystal area and a second single crystal area, and the first single crystal area comprises one row of the two rows of single crystal particles disposed on the first top surface, the second single crystal area comprises another row of the two rows of single crystal particles covering the connecting surface;
wherein, on the connecting surface, particle sizes of single crystal particles of the another row of the two rows of single crystal particles in the second single crystal area are greater than a distance between the first edge and the second edge.

7. The array substrate according to claim 1, wherein in a direction pointing from the first edge to the second edge, a length of the gate is less than or equal to a length of a corresponding row of the two rows of single crystal particles.

8. The array substrate according to claim 1, wherein an insulating pad layer is disposed on a side surface of the active layer close to the base, and the insulating pad layer is disposed on the base and the active defining portion;
wherein a material of the insulating pad layer comprises silicon oxide.

9. The array substrate according to claim 1, wherein the array substrate further comprises:
a source and drain layer, wherein the source and drain layer is disposed on the active layer, and comprises a first electrode electrically connected to the first doped portion and a second electrode electrically connected to the second doped portion; and
a light shielding layer, wherein the light shielding layer is disposed in the base, and comprises a light shielding portion disposed corresponding to the channel portion.

10. A display panel comprising an array substrate, wherein the array substrate comprises a base and a plurality of semiconductor devices disposed on the base;
wherein an active defining portion is provided on the base, and the active defining portion comprises a first bottom surface in contact with a top surface of the base, a first top surface parallel to the first bottom surface, and a connecting surface connected between the first top surface and the first bottom surface and arranged obliquely, wherein a junction of the connecting surface and the first top surface is a first edge, and a junction of the connecting surface and the first bottom surface is a second edge;
wherein any one of the plurality of semiconductor devices comprises:
an active layer, wherein the active layer is disposed on the base and the active defining portion, and comprises a first doped portion, a second doped part and a channel portion disposed between the first doped portion and the second doped portion; and
a gate layer, wherein the gate layer comprises a gate disposed corresponding to the channel portion, and a gate insulating layer is disposed between the gate layer and the active layer;
wherein the active layer comprises one or more single crystal starting points, crystal particles of the active layer grow horizontally and diffusely on the base and the active defining portion in a direction perpendicular to the one or more single crystal starting points, and the one or more single crystal starting points correspond to the first edge; an area where two rows of single crystal particles parallel to the first edge on both sides of the one or more single crystal starting points is a single crystal area, the channel portion is disposed in the single crystal area, and the gate is provided with in a direction perpendicular to the base and covers only one row of the two rows of single crystal particles; and the display panel comprises a plurality of pixel driving circuits, wherein any one of the plurality of pixel driving circuits comprises one or more of the plurality of semiconductor devices.

11. The display panel according to claim 10, wherein an included angle is formed between the first bottom surface and the connecting surface, and the included angle is less than 45°.

12. The display panel according to claim 11, wherein the included angle is greater than or equal to 15° and less than or equal to 30°.

13. The display panel according to claim 10, wherein the gate covers one row of the two rows of single crystal particles disposed on the first top surface in the direction perpendicular to the base;
wherein the first doped portion is disposed on the first top surface, and the second doped portion is disposed on the base and the connecting surface.

14. The display panel according to claim 10, wherein the gate covers one row of the two rows of single crystal particles disposed on the connecting surface in the direction perpendicular to the base;
wherein the first doped portion is disposed on the first top surface, and the second doped portion is disposed on the base.

15. The display panel according to claim 10, wherein an insulating pad layer is disposed on a side surface of the active layer close to the base, and the insulating pad layer is disposed on the base and the active defining portion; wherein a material of the insulating pad layer comprises silicon oxide.

16. The display panel according to claim 10, wherein the single crystal area comprises a first single crystal area and a second single crystal area, and the first single crystal area comprises one row of the two rows of single crystal particles disposed on the first top surface, the second single crystal area comprises another row of the two rows of single crystal particles covering the connecting surface;
wherein, on the connecting surface, particle sizes of single crystal particles in the row of the two rows of single crystal particles in the second single crystal area are greater than a distance between the first edge and the second edge.

17. The display panel according to claim 10, wherein in a direction pointing from the first edge to the second edge, a length of the gate is less than or equal to a length of a corresponding row of the two rows of single crystal particles.

18. The display panel according to claim 16, wherein the array substrate further comprises:
a light shielding layer, wherein the light shielding layer is disposed in the base, and comprises a light shielding portion disposed corresponding to the channel portion.

19. The display panel according to claim 18, wherein under a condition in which the gate is disposed corresponding to the second single crystal area, a length of a corresponding portion of the light shielding portion beyond the first edge is less than or equal to a length of a corresponding portion of the light shielding portion beyond the second edge.

20. The display panel according to claim 10, wherein the active defining portion comprises a groove, an inclined surface of the groove forms the connecting surface of the active defining portion, a portion of the groove in contact with the base and connected with the inclined surface of the groove forms the first bottom surface of the active defining portion, and a portion of the groove parallel with the first bottom surface and connected with the inclined surface of the groove forms the first top surface of the active defining portion.
